(19) United States
(12) Patent Application Publication
(10) Pub. No.: US 2025/0237700 A1
(43) Pub. Date: Jul. 24, 2025

(54) STATE ANALYSIS OF AN ON-LOAD TAP CHANGER

(71) Applicant: Maschinenfabrik Reinhausen GmbH, Regensburg (DE)

(72) Inventors: Sebastian Rehkopf, Regensburg (DE); Markus Zintl, Mitterteich (DE); Markus Dolles, Regensburg (DE); Beate Glaser, Wolnzach (DE)

(21) Appl. No.: 18/848,133

(22) PCT Filed: Mar. 6, 2023
(86) PCT No.: PCT/EP2023/055574

§ 371 Date: Sep. 18, 2024

(30) Foreign Application Priority Data
Mar. 23, 2022 (DE) 10 2022 106 774.2

(51) Int. Cl. G01R 31/327; H01F 29/02

(52) U.S. Cl. CPC G01R 31/327; H01F 29/02

(57) ABSTRACT

A method analyses a state of an on-load tap-changer. The on-load tap-changer has at least one vacuum interrupter for switching between winding taps of a transformer. The method includes: capturing real-time data with respect to the on-load tap-changer; determining tap-changer-specific parameters; and determining at least one characteristic value for ascertaining a state index of the on-load tap-changer on the basis of the real-time data and the tap-changer-specific parameters. The state index includes a period of time until a due maintenance, a remaining service life, or a remaining number of switching processes of the on-load tap-changer.

### CROSS REFERENCE TO RELATED APPLICATIONS

This application is a U.S. National Phase application under 35 U.S.C. § 371 of International Application No. PCT/EP2023/055574, filed on Mar. 6, 2023, and claims benefit to German Patent Application No. DE 10 2022 106 774.2, filed on Mar. 23, 2022. The International Application was published in German on Sep. 28, 2023 as WO 2023/180052 A1 under PCT Article 21 (2).

### FIELD

The present disclosure relates to a method for the state analysis of an on-load tap-changer and to a device for the state analysis of an on-load tap changer.

### BACKGROUND

On-load tap-changers are used for uninterruptibly switching between winding taps of a transformer and are accordingly essential equipment for transformers where particular attention is paid to the reliability thereof. Such on-load tap-changers usually consist of a selector for power-free selection of the respective winding tap of the transformer, which is to be switched to, and a diverter switch for the actual switching from the previous winding tap to the new, preselected winding tap. For this purpose, the diverter switch usually has vacuum interrupters and transition resistors. In this case, the vacuum interrupters serve for connecting the respective winding tap to the load take-off lead, and the transition resistors serve for momentary current limiting during switching.

A vacuum interrupter usually has main switching contacts composed of an arc-resistant copper-tungsten alloy. When the vacuum interrupter is actuated, arcs regularly arise and may melt or vaporize small amounts of the contact material, and thus lead to contact wear or else to irregularities in the contact surface. Furthermore, the vaporized material may cause vapor deposition over the course of the insulation distances in the interior of the vacuum interrupter, which may result in a reduction of the insulation strength of the vacuum interrupter.

Consequently, these processes also influence the service life of a vacuum interrupter and of the on-load tap-changer in which it is used.

The maximum service life of on-load tap-changers and the vacuum interrupters situated therein is usually determined by experiments under worst-case conditions. In order to ensure reliable operation of the on-load tap-changer, on the basis of the results of the experiments carried out, it is necessary to comply with a safety buffer in respect of switching processes of the on-load tap-changer, and the on-load tap-changer may need to be maintained earlier or replaced.

During real operation, the loadings experienced by an on-load tap-changer are generally significantly lower, however.

### SUMMARY

In an embodiment, the present disclosure provides a method of state analysis of an on-load tap-changer. The on-load tap-changer has at least one vacuum interrupter for switching between winding taps of a transformer. The method includes: capturing real-time data with respect to the on-load tap-changer; determining tap-changer-specific parameters; and determining at least one characteristic value for ascertaining a state index of the on-load tap-changer on the basis of the real-time data and the tap-changer-specific parameters. The state index includes a period of time until a due maintenance, a remaining service life, or a remaining number of switching processes of the on-load tap-changer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows one advantageous embodiment of a device in accordance with the improved concept; and

FIG. 2 shows one advantageous embodiment of a method in accordance with the improved concept.

### DETAILED DESCRIPTION

Aspects of the present disclosure specify an improved concept for a state analysis of an on-load tap-changer, which captures the actual loading of the on-load tap-changer and enables the state of the on-load tap-changer to be assessed more accurately.

In accordance with a first aspect of the improved concept, a method for the state analysis of an on-load tap-changer is specified, wherein the on-load tap-changer has at least one vacuum interrupter for switching between winding taps of a transformer. The method comprises the following steps:
capturing real-time data with respect to the on-load tap-changer,
determining tap-changer-specific parameters,
determining at least one characteristic value for ascertaining a state index of the on-load tap-changer on the basis of the real-time data and the tap-changer-specific parameters,
wherein:
   the state index comprises a period of time until a due maintenance and/or a remaining service life and/or a remaining number of switching processes of the on-load tap-changer.

The advantage of the described method over the prior art is that, as a result of capturing the real-time data taking account of the tap-changer-specific parameters, the at least one characteristic value determined represents the actual loading experienced by the on-load tap-changer. Knowledge of the actual state of the on-load tap-changer enables optimization of the maintenance intervals and of the utilization of the on-load tap-changer in general and an increased service life. Moreover, capturing the actual loading enables the occurrence of critical states of the on-load tap-changer to be recognized and avoided at an early stage.

In accordance with one preferred embodiment, capturing real-time data comprises determining the load current during each switching process, and/or determining the step voltage during each switching process, and/or determining the present position of the on-load tap-changer, and/or determining the switching direction of an imminent switching process, i.e. determining whether the transmission ratio of the transformer is increased or decreased, and/or determining a temperature of an insulating medium in which the vacuum interrupter is situated, and/or determining the switching frequency in a defined period of time, and/or determining the duration of a switching process, and/or determining an arc burning duration during each switching process.

Furthermore, it is possible to determine for example the duration and level of a circulating current flowing through the on-load tap-changer during the switching process, or further temperatures, for example the temperature at the vacuum interrupters or the transition resistors of the on-load tap-changer.

In this case, the term determining is understood to mean the capturing of data, for example by measurement by means of suitable sensors, and the further processing of data, for example in the form of calculations on the basis of the captured data for determining further relevant characteristic variables.

In accordance with one embodiment, the tap-changer-specific data comprise the number and dimensioning of the transition resistors, the circuit topology of the on-load tap-changer, in particular the interconnection of the vacuum interrupters, or the number and dimensioning of the vacuum interrupters.

In accordance with a further embodiment, the tap-changer-specific data comprise in particular specific data of the at least one vacuum interrupter.

Specific data of the vacuum interrupter comprise characteristic parameters of the vacuum interrupter such as the contact material, the geometry of the tube or limit values determined by experiments, such as, for example, wear limit values, the average arc burning duration or the average arc energy.

In accordance with one preferred embodiment, the at least one characteristic value comprises contact wear.

The contact wear relates to the wear of contact material of the main switching contacts of the vacuum interrupter as a consequence of arcs arising. Preferably, the contact wear is captured in units of volume.

In accordance with a further embodiment, in addition to the contact wear, a reduction of the insulation strength of the vacuum interrupter and/or irregularities on the contact surface are/is determined as characteristic values.

As a result of the arc, which is usually extinguished at the first zero crossing of the current, contact material vaporizes and a metal vapor arises which spreads and correspondingly condenses in the vacuum interrupter and, as a result, can adversely affect the insulation strength of the vacuum interrupter.

Moreover, the melting or vaporizing of contact material can contribute to irregularities arising in the contact surface, which can in turn adversely affect the extinguishing of the arc at the zero crossing, for example by virtue of restrikes occurring.

In accordance with a further embodiment, the at least one characteristic value comprises a state of the vacuum within the vacuum interrupter.

In accordance with a further embodiment, the at least one characteristic value is compared with a defined limit value and a message is output in the case where the limit value is exceeded.

By way of example, a specific volume of vaporized contact material or the thickness of a metal vapor layer that deposits in the interior of the vacuum interrupter over the course of the insulation distance owing to the extinguishing of the arc can be defined as limit value. A specific number of irregularities on the contact surface can likewise be used as limit value.

In accordance with a further embodiment, the method comprises the following further step:
determining the operating conditions present in the on-load tap-changer and the vacuum interrupter on the basis of the real-time data and the tap-changer-specific parameters.

When determining the operating conditions, the application in which the on-load tap-changer is operated, in other words the location of use of the transformer, is concomitantly included in the state analysis. This is because depending on how often the on-load tap-changer is actuated, and on the duration and level of a circulating current flowing in the on-load tap-changer in the process, accordingly on the magnitude of the contact heating and the power class for which the on-load tap-changer is designed, the influence on the state may have varying effects.

By way of example, in the case of on-load tap-changers used in transformers in arc furnaces, a certain number of no-load switching processes are carried out, in which the on-load tap-changer is actuated but no current is switched. In this case, the on-load tap-changer only experiences a mechanical stress, which generally has less influence on the state index than a switching process in which current flows and an arc is extinguished.

In accordance with a further embodiment, determining the at least one characteristic value takes place on the basis of model simulation and/or machine learning methods and/or interpolation methods and/or historical data.

By way of example, suitable electrohydrodynamics models or models pertaining to particle spreading or arc formation can be used in the model simulation. It is equally possible to simulate mechanical loadings, for example the loading on the bellows of a vacuum interrupter, and electrical circuits using suitable software.

The characteristic value can be determined for example using an artificial neural network as methodology in the field of machine learning. It is likewise possible to apply a regression algorithm or other known machine learning methods.

In the case where historical data are considered, results from experiments conducted with comparable data and parameters or conclusions drawn from field experience equipment are used, for example. A superordinate database, for example a cloud, comprising data of an entire fleet of transformers, can also serve as a data source for historical data.

In accordance with a second aspect of the improved concept, a device for the state analysis of an on-load tap-changer is specified.

With regard to the device, reference is analogously made to the previous explanations, preferred features, effects and/or advantages that have already been explained for the method. There is therefore no corresponding repetition.

In accordance with the second aspect of the improved concept, the device is configured for the state analysis of an on-load tap-changer, wherein the on-load tap-changer has at least one vacuum interrupter for switching between winding taps of a transformer, and the device comprises an evaluation unit and a data memory. Real-time data with respect to the on-load tap-changer and tap-changer-specific parameters are storable in the data memory. Moreover, the data memory can comprise further relevant data such as, for example, application-specific parameters, limit values or historical data that are used for the state analysis. The evaluation unit is communicatively connected to the data memory and/or to a superordinate control system and is configured to carry out a method in accordance with the first aspect of the improved concept.

For example, a control system of a utility can function as a superordinate control system.

In accordance with one embodiment, the device additionally comprises an output unit for outputting a state index of the on-load tap-changer. The output unit can furthermore be configured to output an action recommendation or warning message depending on the state index.

For this purpose, the output unit can have correspondingly suitable visualization means, for example a screen or LED illuminants that signal a critical state, for example.

In accordance with a further embodiment, the on-load tap-changer and the transformer have sensors suitable for capturing the real-time data, such as, for example, a current sensor on the primary and/or secondary side of the transformer or a temperature sensor in the insulating medium of the on-load tap-changer.

The present disclosure is explained below in detail on the basis of exemplary embodiments with reference to the drawings. Components which are identical or functionally identical or which have an identical effect may be provided with identical reference signs. Identical components or components with an identical function are in some cases explained only in relation to the figure in which they first appear. The explanation is not necessarily repeated in the subsequent figures.

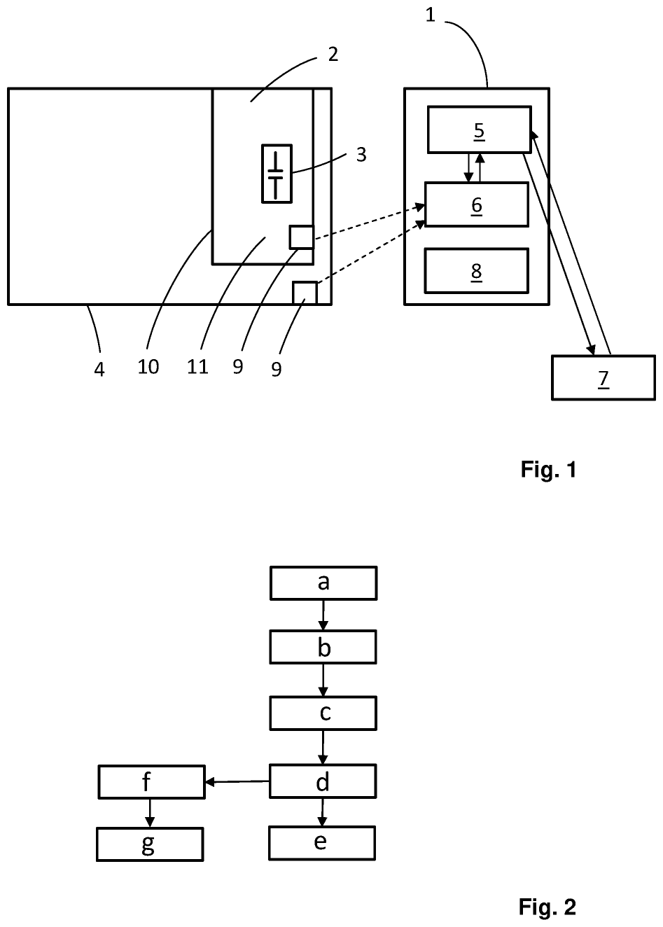

FIG. 1 shows one advantageous embodiment of a device 1 in accordance with the improved concept in a schematic illustration.

The device 1 serves for the state analysis of an on-load tap-changer 2 having a vacuum interrupter 3 for switching between winding taps of a transformer 4. The vacuum interrupter 3 is situated in a housing 10 of the on-load tap-changer 2, said housing being at least partly filled with insulating medium 10. In principle, however, the tap changer 2 together with vacuum interrupter 3 can also be arranged without a housing in the transformer 4, such that the tap changer 2 is situated in the oil system of the transformer 4. In FIG. 1, only one vacuum interrupter is depicted by way of example and for the sake of better clarity. In general, however, the on-load tap-changer 2 has a plurality of vacuum interrupters 3 for switching purposes.

The device 1 comprises an evaluation unit (evaluator) 5, a data memory 6 and an output unit (output) 8. In the data memory 6, data relevant to carrying out the state analysis are stored, such as real-time data with respect to the on-load tap-changer 2, specific parameters of the on-load tap-changer 2 and of the vacuum interrupter 3, limit values of relevant characteristic values or historical data which are used for determining the state of the on-load tap-changer 2 and of the vacuum interrupter 3. For capturing the real-time data, the on-load tap-changer 2 and the transformer 4 each have a sensor 9. In accordance with the embodiment shown in FIG. 1, the tap changer 2 has for example a temperature sensor 9 for measuring the temperature of the insulating medium 11, and the transformer 4 has for example a current sensor 9 on the primary and/or secondary side. In principle, however, even further sensors 9 can be provided for capturing the real-time data.

The evaluation unit 5 is communicatively connected to the data memory 6 and configured to obtain the real-time data and parameters specific to the tap changer and the vacuum interrupter and, on the basis thereof, to determine at least one characteristic value for ascertaining a state index of the on-load tap-changer 2. In addition to the data memory 6, the evaluation unit 5 in accordance with this embodiment is communicatively connected to a superordinate control system 7, for example the control system of a utility, and can obtain further data for determining the characteristic value via this connection. The characteristic value is determined on the basis of model simulation, machine learning methods, interpolation methods, historical data or combinations thereof.

The explained functionalities of the evaluation unit 5 can be implemented by hardware, firmware, software, other machine-readable command codes or a combination thereof.

The state index is output via the output unit 8. For this purpose, the output unit 8 has corresponding visualization means, such as a screen, for example.

FIG. 2 illustrates one advantageous embodiment of a method in accordance with the improved concept in the form of a flowchart.

With regard to the method, reference is analogously made to the previous explanations, preferred features, effects and/or advantages that have already been explained for the device 1 in regard to FIG. 1. There is therefore no corresponding repetition.

The advantageous embodiment of the method serves for the state analysis of an on-load tap-changer having at least one vacuum interrupter for switching between winding taps of a transformer. The method preferably serves for the state analysis of an on-load tap-changer 2 in a transformer 4 with a device 1 as illustrated in FIG. 1.

In a step a, real-time data with respect to the on-load tap-changer 2 are captured by means of suitable sensors 9. Real-time data are for example the load current flowing during each switching process or the applied step voltage, the present position n of the on-load tap-changer, the switching direction of an imminent switching process, the temperature of the insulating medium surrounding the vacuum interrupter, the switching frequency in a defined period of time, the duration of a switching process or the arc burning duration during each switching process.

A step b involves determining tap-changer-specific parameters such as, for example, the number and dimensioning of the transition resistors, the circuit topology of the on-load tap-changer, in particular the interconnection of the vacuum interrupters, or the number and dimensioning of the vacuum interrupters, and also specific data of the vacuum interrupters. Specific data of a vacuum interrupter comprise characteristic parameters such as the contact material, the geometry of the tube and the kinematics of the tube actuation or limit values determined by experiments, such as, for example, wear limit values, the average arc burning duration or the average arc energy. Opening and closing speeds of the tube and the internal pressure of the vacuum interrupter can likewise be taken into account as specific parameters of the vacuum interrupter.

A step c involves determining the operating conditions present in the on-load tap-changer 2 and the vacuum interrupter 3, for example the switching frequency, duration and level of the circulating current flowing upon the actuation, or the contact heating, on the basis of the real-time data, the tap-changer-specific parameters and the specific data of the vacuum interrupter 3.

The carrying out of steps a, b and c is not restricted to the order shown in the flowchart in FIG. 2. By contrast, steps a, b and c can also be carried out in an opposite and/or interchanged order with respect to one another or simultaneously.

A step d involves determining at least one characteristic value for ascertaining a state index of the on-load tap-changer 2 on the basis of the real-time data, the tap-changer-specific parameters and the specific data of the vacuum interrupter 3. In this case, the state index comprises a period of time until a due maintenance and/or a remaining service life and/or a remaining number of switching processes of the on-load tap-changer 2.

In accordance with this embodiment, the at least one characteristic value for ascertaining the state index is configured as contact wear. In principle, however, the method according to the present disclosure is not restricted to this characteristic value. By contrast, even further characteristic values such as a reduction of the insulation strength of the vacuum interrupter caused by metal vapor or irregularities on the contact surface can also be determined as characteristic values.

The characteristic value and the further characteristic values, if appropriate, are determined on the basis of model simulation, machine learning methods, interpolation methods, historical data or combinations thereof.

In a step e, the state index is output by means of the output unit 8.

Independently of the outputting of the state index, in accordance with this specific embodiment, in a step f, the determined characteristic value is compared with a defined limit value and in the case where the limit value is exceeded, in step g, an additional warning message is output by means of the output unit 8.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE SIGNS

1 Device
2 On-load tap-changer
3 Vacuum interrupter
4 Transformer
5 Evaluation unit
6 Data memory
7 Superordinate control system
8 Output unit
9 Sensor
10 Housing
11 Insulating medium

1. A method for a state analysis of an on-load tap-changer, the on-load tap-changer comprising at least one vacuum interrupter for switching between winding taps of a transformer, the method comprising:
capturing real-time data with respect to the on-load tap-changer;
determining tap-changer-specific parameters; and
determining at least one characteristic value for ascertaining a state index of the on-load tap-changer on the basis of the real-time data and the tap-changer-specific parameters,
wherein the state index comprises a period of time until a due maintenance, a remaining service life, or a remaining number of switching processes of the on-load tap-changer.

2. The method as claimed in claim 1, wherein capturing the real-time data comprises:
determining a load current during each switching process of the on-load tap-changer, or
determining a step voltage during each switching process,
determining a present position of the on-load tap-changer,
determining a switching direction of an imminent switching process of the on-load tap-changer,
determining a temperature of an insulating medium in which the vacuum interrupter is situated,
determining a switching frequency in a defined period of time,
determining a duration of a switching process of the on-load tap-changer, or
determining an arc burning duration during each switching process of the on-load tap-changer.

3. The method as claimed in claim 1, wherein;
the tap-changer-specific parameters comprise specific data of the at least one vacuum interrupter.

4. The method as claimed in claim 1, wherein:
the at least one characteristic value comprises contact wear, a reduction of an insulation strength of the vacuum interrupter, or irregularities on a contact surface.

5. The method as claimed in claim 1, wherein the method further comprises:
comparing the at least one characteristic value with a defined limit value; and
outputting a message in a case where the at least one characteristic value exceeds the defined limit value.

6. The method as claimed in claim 1, wherein the method further comprises:
determining the operating conditions present in the on-load tap-changer and the vacuum interrupter on the basis of the real-time data and the tap-changer-specific parameters.

7. The method as claimed in claim 1, wherein:
determining the at least one characteristic value takes place on the basis of model simulation, machine learning methods, interpolation methods, or historical data.

8. A device for the state analysis of the on-load tap-changer, the on-load tap-changer comprising the at least one vacuum interrupter for switching between winding taps of the transformer, the device comprising:
an evaluator; and
a data memory,
wherein:
the real-time data with respect to the on-load tap-changer and the tap-changer-specific parameters are stored in the data memory, and
the evaluator is communicatively connected to the data memory or to a superordinate control system, and is configured to carry out the method as claimed in claim 1.

9. The device as claimed in claim 8, furthermore comprising
an output configured for outputting the state index of the on-load tap-changer.

10. The device as claimed in claim 8, wherein;
the on-load tap-changer and the transformer have sensors suitable for capturing the real-time data.
